(19) United States
(12) Patent Application Publication
(10) Pub. No.: US 2009/0148604 A1
(43) Pub. Date: Jun. 11, 2009

(54) Substrate Processing Apparatus and Device Manufacturing Method

(75) Inventors: Raimond VISSER, Best (NL); Pieter Renaat Maria Hennus, Peer (BE); Johannes Hendrikus Gertrudis Franssen, Eersel (NL); Erwin Theodorus Jacoba Verhagen, Veldhoven (NL)

Correspondence Address: STERNE, KESSLER, GOLDSTEIN & FOX P.L.L.C., 1100 NEW YORK AVENUE, N.W., WASHINGTON, DC, 20005, US

(73) Assignee: ASML Netherlands B.V., Veldhoven (NL)

(21) Appl. No.: 12/271,362

(22) Filed: Nov. 14, 2008

Related U.S. Application Data
(60) Provisional application No. 60/996,395, filed on Nov. 15, 2007.

(51) Int. Cl. B05D 3/00; C23C 14/00

(52) U.S. Cl. 427/294; 118/50; 118/50.1

(57) ABSTRACT

An exemplary substrate processing apparatus has a vacuum chamber and a load lock for gas removal. The load lock has a support table to support a substrate. A cover plate may be provided in the load lock, the cover plate having a lower surface facing the upper surface of the support table. Openings may be provided in the lower surface of the cover plate to allow removal of gas from over the substrate in a direction substantially normal to the lower surface. In an embodiment, a gas pressure between the upper surface of the support table and the substrate is initially reduced through the opening to a certain pressure below a concurrent load lock pressure. When the remainder of the load lock pressure has dropped below the certain, gas pressure between the upper surface of the support table and the substrate is reduced together with the remainder load lock pressure.

### CROSS-REFERENCE TO RELATED APPLICATIONS

The present application claims the benefit of U.S. Provisional Patent Application No. 60/996,395, filed Nov. 15, 2007, which is incorporated by reference herein in its entirety.

### FIELD

Embodiments of the present invention relate to a substrate processing apparatus, such as a lithographic apparatus and a method for manufacturing a device.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. including part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

It is desirable to irradiate substrates with the pattern in a vacuum environment. In order to achieve a high processing rate, it is desirable to maintain this vacuum environment continuously even when substrates have to be transported between the vacuum environment and a non-vacuum environment. European Patent Application Publication No. EP 1 457 830, incorporated herein by reference in its entirety, describes the use of a load lock for this purpose. A load lock acts like a lock for ships in a canal, providing a relatively small space that can be opened to two environments alternately, enabling the pressure to be raised and lowered in the small space while the pressures on the other sides of the doors remain substantially unaffected.

European Patent Application Publication No. EP 1 457 830 describes that adiabatic cooling of the gas in the load lock during evacuation may give rise to undesirable cooling of the substrate. The substrate rests on bumps on the top surface of a support unit. Typically very narrow bumps are used to minimize contamination of the substrate. Unfortunately, such bumps may lead to a poor heat contact which does not prevent cooling. To address the cooling problem, various measures are proposed. In one measure a temperature stabilized support unit is provided for the substrate in the load lock. A temperature stabilized fluid circulation circuit runs through the support unit. Gas is introduced in the space around the bumps to improve thermal conduction between the substrate and the support unit. Rims are provided at the edge of the support unit to prevent the gas underneath the substrate from flowing into the load lock. The substrate is clamped to the support unit, so that the substrate cannot be blown off by the gas underneath it when the load lock is evacuated.

EP 1 457 830 provides a cover plate in the load lock over the substrate. In an embodiment the support unit and the cover plate are moved towards each other after the substrate has been placed on the support unit. The cover plate functions to reduce gas flow over the substrate, which could affect temperature. In an embodiment a cover plate is provided fixed to the support unit, the fluid circulation circuit running through the cover plate as well.

Furthermore, EP 1 457 830 proposes to use an initial partial reduction of the gas pressure in the load lock followed by an intermediate period wherein the pressure is kept constant for some time before the load lock is completely evacuated. This intermediate period provides an extended period of thermal conduction between the substrate and the temperature-stabilized walls of the load lock after the initial adiabatic cooling due to the initial pressure reduction.

The load lock limits the speed with which substrates can be entered and removed from, for example, the exposure portion of a lithographic apparatus. It forms a limiting factor for the throughput of the lithographic apparatus. It would be desirable to minimize the time interval that substrates have to spend in the load lock. However, increased evacuation speed compromises temperature stability. Also or alternatively, the distance to the cover plate may make it ineffective as a thermal stabilizer.

### SUMMARY

The inventors have discovered a method and apparatus to limit temperature effects when a high operating speed is used for a load lock.

According to an aspect of the invention, there is provided a substrate processing apparatus with a processing chamber. The apparatus may include a load lock for gas removal with a first door to allow entry of a substrate and a second door to allow exit of the substrate directly or indirectly to the processing chamber; a support table, in the load lock, having an upper surface to support the substrate; and a cover plate in the load lock, the cover plate having a lower surface facing the upper surface of the support table, wherein openings are provided in the lower surface of the cover plate to allow removal of gas from above the substrate in a direction substantially normal to the lower surface.

According to an aspect of the invention, there is provided a substrate processing apparatus with a processing chamber. The apparatus may include a load lock for gas removal with a first door to allow entry of a substrate and a second door to allow exit of the substrate directly or indirectly to the processing chamber; a temperature stabilized support table in the load lock to support the substrate, the support table including a plurality of equal height bumps on an upper surface of the support table; and a gas removing arrangement including an opening in the upper surface of the support table, the gas removing arrangement being configured to reduce a gas pressure between the upper surface of the support table and the substrate initially through the opening to a certain pressure below a concurrent load lock pressure in a remainder of the load lock, and to reduce the gas pressure between the upper surface of the support table and the substrate together with the load lock pressure in the remainder of the load lock when the load lock pressure in the remainder of the load lock has dropped below the certain pressure.

According to an aspect of the invention, there is provided a substrate processing apparatus with a processing chamber. The apparatus may include a load lock with a first door to allow entry of a substrate and a second door to allow exit of the substrate directly or indirectly to the processing chamber; a buffer vessel coupled to the load lock to supply gas when the load lock is vented, the buffer vessel having a volume that is larger than a volume of the load lock and/or is coupled to the load lock via a diffuser; a pressure stabilizer coupled to the buffer vessel; a valve coupled between the buffer vessel and the load lock; and a control unit configured to cause the pressure stabilizer to stabilize gas pressure in the buffer vessel while the valve is closed and to open the valve when the load lock is vented.

According to an aspect of the invention, there is provided a photolithographic apparatus with a processing chamber. The apparatus may include a support constructed to support a patterning device, the patterning device being capable of imparting the radiation beam with a pattern in its cross-section to form a patterned radiation beam; a substrate table constructed to hold a substrate in the processing chamber; a projection system configured to project the patterned radiation beam onto a target portion of the substrate in the processing chamber; a coating application device configured to apply a coating to the substrate; a load lock between the coating application device and the processing chamber, the load lock having a first door for transport from the coating application device and a second door for transport towards the processing chamber; and a substrate inspection system configured to inspect at least a part of the substrate that will not be patterned using the patterned beam, after coating and before entry into the load lock.

According to an aspect of the invention, there is provided a photolithographic apparatus with a processing chamber. The apparatus may include a support constructed to support a patterning device, the patterning device being capable of imparting the radiation beam with a pattern in its cross-section to form a patterned radiation beam; a substrate table constructed to hold a substrate in the processing chamber; a projection system configured to project the patterned radiation beam onto a target portion of the substrate in the processing chamber; a coating application device for applying a coating to the substrate; and a load lock between the coating application device and the processing chamber, the load lock having a first door towards the coating application device and a second door toward the processing chamber, the load lock having a third door for entering substrates without going through the coating application device.

According to an aspect of the invention, there is provided a device manufacturing method, including processing the substrate in a processing chamber; passing the substrate to the processing chamber through a load lock; inserting the substrate in the load lock between a support table and a cover plate; removing gas from the load lock; and removing gas from a region between the substrate and the cover plate to the load lock in a direction that is substantially normal to a surface of the substrate, through openings in the cover plate.

According to an aspect of the invention, there is provided a device manufacturing method, including processing the substrate in a processing chamber; passing the substrate to the processing chamber through a load lock; inserting the substrate in the load lock over a temperature stabilized support table, the support table including a plurality of equal height bumps on an upper surface of the support table supporting the substrate, an opening being present in the upper surface of the support table; reducing a gas pressure between the upper surface of the support table and the substrate initially to a certain pressure below a concurrent load lock pressure in a remainder of the load lock by removing gas through the openings from a space between the upper surface of the support table and the substrate, when the substrate rests on the bumps; and reducing the gas pressure between the upper surface of the support table and the substrate together with the load lock pressure in the remainder of the load lock when the load lock pressure in the remainder of the load lock has dropped below the certain pressure.

According to an aspect of the invention, there is provided a device manufacturing method, including processing a substrate in a processing chamber; passing the substrate from the processing chamber through a load lock; regulating gas pressure in a buffer vessel at least while the buffer vessel is not in communication with the load lock; and venting the load lock by providing a gas flow connection between the buffer vessel and the load lock.

According to an aspect of the invention, there is provided a device manufacturing method, including applying a photoresist coating to a substrate; passing the substrate to a processing chamber via a load lock after the substrate has been coated; projecting a patterned radiation beam onto a target portion of the substrate in the processing chamber; and automatically inspecting at least a part of the substrate that will not be patterned using the patterned beam, after coating and before entry into the load lock.

According to an aspect of the invention, there is provided a device manufacturing method, including applying a photoresist coating to the substrate; passing the substrate to a load lock via a first door of the load lock after the substrate has been coated; passing the substrate from the load lock to a processing chamber via a second door of the load lock after the substrate has been coated; projecting a patterned radiation beam onto a target portion of the substrate in the processing chamber; and cleaning and/or calibrating an apparatus that is used to manufacture the device by introducing and/or removing a further substrate, from which no devices are manufactured, via a third door of the load lock.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS

The accompanying drawings, which are incorporated herein and form part of the specification, illustrate embodiments of the present invention and, together with the description, further serve to explain the principles of the invention and to enable a person skilled in the relevant art(s) to make and use the invention.

FIG. 1 shows a lithographic apparatus according to an embodiment of the present invention.

FIGS. 2a-d show a load lock, according to embodiments of the present invention.

FIG. 3 shows a detail of a support table, according to an embodiment of the present invention.

FIG. 4 shows a support table with gas removing connections, according to an embodiment of the present invention.

FIG. 5 shows a support table and a cover plate, according to an embodiment of the present invention.

FIG. 6 shows a lithographic apparatus with an inspection system, according to an embodiment of the present invention.

FIG. 7 shows a load lock according to an embodiment of the present invention.

FIG. 8 shows a load lock with a buffer vessel, according to an embodiment of the present invention.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

### DETAILED DESCRIPTION

This specification discloses one or more embodiments that incorporate the features of this invention. The disclosed embodiment(s) merely exemplify the invention. The scope of the invention is not limited to the disclosed embodiment(s). The invention is defined by the claims appended hereto.

The embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present invention may be implemented.

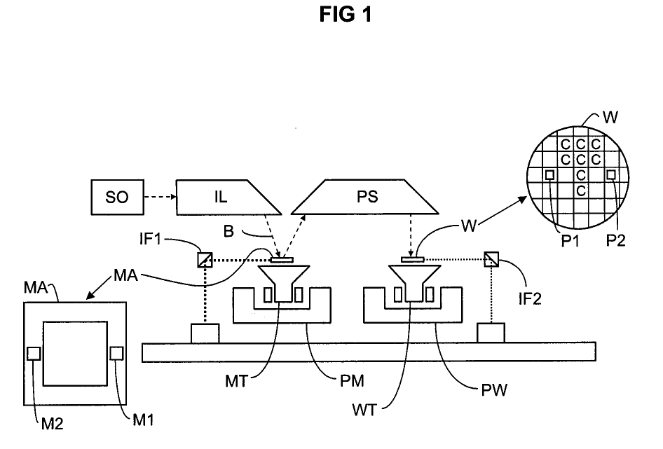

FIG. 1 schematically depicts a lithographic apparatus according to one embodiment of the invention. The apparatus includes:
an illumination system (illuminator) IL configured to condition a radiation beam B (e.g. UV radiation or EUV radiation);
a support structure (e.g. a mask table) MT constructed to support a patterning device (e.g. a mask) MA and connected to a first positioner PM configured to accurately position the patterning device in accordance with certain parameters;
a substrate table (e.g. a wafer table) WT constructed to hold a substrate (e.g. a resist-coated wafer) W and connected to a second positioner PW configured to accurately position the substrate in accordance with certain parameters; and
a projection system (e.g. a refractive projection lens system) PS configured to project a pattern imparted to the radiation beam B by patterning device MA onto a target portion C (e.g. including one or more dies) of substrate W.

The illumination system may include various types of optical components, such as refractive, reflective, magnetic, electromagnetic, electrostatic or other types of optical components, or any combination thereof, for directing, shaping, or controlling radiation.

The support structure holds the patterning device in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a reflective type (e.g. employing a reflective mask). Alternatively, the apparatus may be of a transmissive type (e.g. employing a transmissive mask).

The lithographic apparatus may be of a type having two (dual stage) or more substrate tables (and/or two or more patterning device support structures). In such “multiple stage” machines the additional tables and/or support structures may be used in parallel, or preparatory steps may be carried out on one or more tables and/or support structures while one or more other tables and/or support structures are being used for exposure.

The lithographic apparatus may also be of a type wherein at least a portion of the substrate may be covered by a liquid having a relatively high refractive index, e.g. water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIG. 1, illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from source SO to illuminator IL with the aid of a beam delivery system including, for example, suitable directing mirrors and/or a beam expander. In other cases the source may be an integral part of the lithographic apparatus, for example when the source is a mercury lamp. Source SO and illuminator IL, together with the beam delivery system BD if required, may be referred to as a radiation system.

Illuminator IL may include an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, illuminator IL may include various other components, such as an integrator and a condenser. The illuminator may be used to condition the radiation beam, to have a desired uniformity and intensity distribution in its cross-section.

Radiation beam B is incident on patterning device (e.g., mask) MA, which is held on support structure (e.g., mask table) MT, and is patterned by the patterning device. Having traversed patterning device MA, radiation beam B passes through projection system PS, which focuses the beam onto a target portion C of substrate W. With the aid of second positioner PW and position sensor IF2 (e.g. an interferometric device, linear encoder or capacitive sensor), substrate table WT can be moved accurately, e.g. so as to position different target portions C in the path of radiation beam B. Similarly, first positioner PM and another position sensor IF1 can be used to accurately position patterning device MA with respect to the path of the radiation beam B, e.g. after mechanical retrieval from a mask library, or during a scan. In general, movement of support structure MT may be realized with the aid of a long-stroke module (coarse positioning) and a short-stroke module (fine positioning), which form part of first positioner PM. Similarly, movement of substrate table WT may be realized using a long-stroke module and a short-stroke module, which form part of second positioner PW. In the case of a stepper (as opposed to a scanner) support structure MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on patterning device MA, the patterning device alignment marks may be located between the dies.

The depicted apparatus may be used in at least one of the following modes:

1. In step mode, support structure MT and substrate table WT are kept essentially stationary, while an entire pattern imparted to the radiation beam is projected onto a target portion C at one time (i.e. a single static exposure). Substrate table WT is then shifted in the X and/or Y direction so that a different target portion C can be exposed. In step mode, the maximum size of the exposure field limits the size of the target portion C imaged in a single static exposure.

2. In scan mode, support structure MT and substrate table WT are scanned synchronously while a pattern imparted to the radiation beam is projected onto a target portion C (i.e. a single dynamic exposure). The velocity and direction of substrate table WT relative to support structure MT may be determined by the (de-)magnification and image reversal characteristics of projection system PS. In scan mode, the maximum size of the exposure field limits the width (in the non-scanning direction) of the target portion in a single dynamic exposure, whereas the length of the scanning motion determines the height (in the scanning direction) of the target portion.

3. In another mode, support structure MT is kept essentially stationary holding a programmable patterning device, and substrate table WT is moved or scanned while a pattern imparted to the radiation beam is projected onto a target portion C. In this mode, generally a pulsed radiation source is employed and the programmable patterning device is updated as required after each movement of substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

A high vacuum is maintained in the chamber that contains substrate table WT. Substrates W enter the lithographic apparatus from outside, where atmospheric gas pressure pertains. At the interface between the vacuum space and the outside the lithographic apparatus is provided with a load lock. The gas pressure of the load lock is cycled between outside pressure (or slightly higher pressure) and vacuum pressure, while the main vacuum space of the lithographic apparatus remains vacuum. Substrates are entered into the load lock and taken out when the interior of the load lock is at outside pressure and at vacuum pressure respectively.

A high throughput speed of substrates through the load lock is desirable. The throughput speed may be limited by the need to bring substrates uniformly to an accurately defined temperature before a pattern can be projected onto it. Due to adiabatic expansion of the gas in a load lock during rapid evacuation, the temperature of the substrate and the uniformity of this temperature may be compromised. This may have a delaying effect, which may be exacerbated by the vacuum conditions because they reduce heat transport. The effect on substrate temperature may be strongest when the gas pressure is still high.

A problem may arise because the load lock can be a source of contamination, both due to contamination that remains from previous substrates and/or due to dislodging caused by the effects of rapid gas flow. If the load lock passes on too much contamination to the main vacuum space, there may arise a need to return the main vacuum space to atmospheric pressure, which may cause a significant loss of production time.

A similar problem may arise when a load lock is used between environments with different gas content. In this case, the load lock will be evacuated and subsequently refilled with a different type of gas, or when the load lock is used to realize a reduced pressure. The embodiments described below may be used for such a load lock as well. However, for the sake of simplicity an example with a vacuum processing chamber will be described. One or more problems discussed herein may be most significant in the vacuum processing situation due to the absence of thermal transport through gas in vacuum.

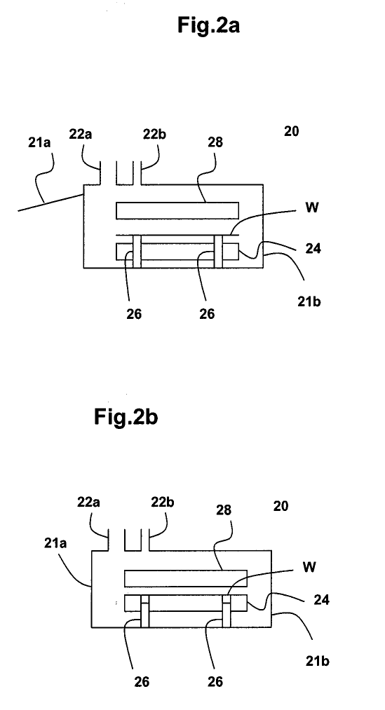

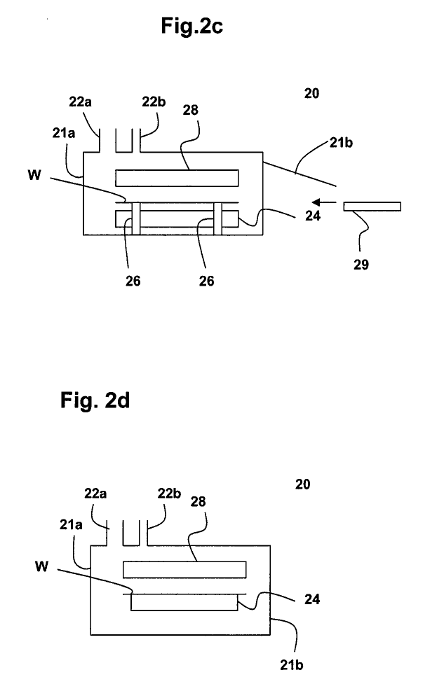

FIGS. 2a-c show an exemplary load lock 20 with first and second doors 21a,b towards the outside of the lithographic apparatus and a vacuum space of the lithographic apparatus respectively. Load lock 20 has a pump connection 22a and a venting connection 22b to allow removal and supply of gas respectively. In operation, when a substrate W is entered into the lithographic apparatus, substrate W is inserted through first door 21a as shown in FIG. 2a, which is subsequently closed. Load lock 20 is then evacuated through pump connection 22a as shown in FIG. 2b, until a sufficiently low pressure is reached. Subsequently, second door 21b to the vacuum space is opened, as shown in FIG. 2c, and substrate W is taken out of load lock 20. When a substrate W is removed from the lithographic apparatus the reverse procedure is followed. Substrate W is inserted through second door 21b, which is subsequently closed. Load lock 20 is then returned to outside pressure by supply of gas via venting connection 22b. Subsequently, first door 21a to the outside is opened and substrate W is taken out of load lock 20.

As shown in FIGS. 2a-c, load lock 20 includes a support table 24, support pins 26, and a cover plate 28. A gripper 29 of a robot to grip substrate W from load lock and move substrate W into the vacuum space is shown by way of example. A movement driving mechanism (not shown) is coupled to support table 24 to move support table 24 vertically relative to support pins 26. Support table 24 and cover plate 28 are coupled to a temperature stabilizer system (not shown), and support table 24 and cover plate 28 are coupled to a support structure (not shown). The structure of the temperature stabilizer system may act as support structure for support table 24 and cover plate 28 as well. The temperature stabilizer system may include pipes through which temperature stabilized fluid is circulated, and which are in contact with support table 24 and cover plate 28 or run through their body. Heat pump structures may be used, or heater resistances and cooling elements such as a Peltier element, or combination of fluid circulation, heating, cooling and/or heat pumping.

Support pins 26 run through support table 24 in a vertical direction. Support table 24 is vertically movable relative to support pins 26. Although support pins 26 are shown supported on the load lock floor for the sake of simplicity, it should be understood that a different support may be used. Cover plate 28 faces support table 24. In an embodiment, both support table 24 and cover plate 28 have a width that is larger than the width of substrate W so that substrate W fits within the periphery of both support table 24 and cover plate 28. The distance between the tips of support pins 26 and the cover plate 28 may be about 10 mm, for example.

In exemplary operation, when a substrate is entered, support table 24 is initially at a low position relative to support pins 26, as shown in FIG. 2a. This makes it possible to place substrate W onto support pins 26 with a gripper that reaches below substrate W. Subsequently support table 24 is raised relative to the support pins 26, so that substrate W comes to rest on support table 24 instead of, or in addition to, on support pins 26. In an embodiment, cover plate 28 is kept at a fixed position when support table 24 is raised. In an embodiment, support table 24 is raised relative to support pins 26 so that substrate W is raised to a position closer to cover plate 28 than when it rests on support pins 26, without forcing substrate W into contact with cover plate 28. The distance between substrate W and cover plate 28 may be reduced by a factor of three, for example. In an embodiment, it is reduced from approximately 10 mm to approximately 3 mm. Cover plate 28 may be lowered to reduce the distance. After pressure has been sufficiently reduced, second door 21b is opened and support table 24 is lowered relative to support pins 26 so that substrate W comes to rest on support pins 26, with sufficient space to allow for a gripper 29 that extends below substrate W, as shown in FIG. 2c.

During lowering of the pressure, support table 24 and cover plate 28 act as heat sinks to stabilize the temperature of substrate W. Heat transfer occurs through the gas in load lock 20, contact between support table 24, and radiation between substrate W, support table 24 and cover plate 28. The gas near substrate W is kept near the stabilized temperature of support table 24 and cover plate 28 as a result of the proximity of support table 24 and cover plate 28 to substrate W. Support table 24 is brought into closer proximity with substrate W by raising support table 24 relative to support pins 26 during removal of gas. In an embodiment, during removal of gas, substrate W is also kept in closer proximity to cover plate 28 by raising substrate W relative to support pins 26 with support table 24.

When substrates are moved out of the vacuum space through load lock 20 they may be placed on support table 24, or on the pins that extend through this table. However, in an embodiment, a further support is provided in load lock 20, such as a rack (not shown), to place a substrate W that is moved out. The substrate may remain on the further support while atmospheric pressure is reached. This support has an advantage that a substrate that is moved out can be inserted in load lock 20 before another substrate that is moved in has been taken off support table 24. This makes it possible to speed up processing, for example by allowing a robot to deposit a substrate in load lock 20 and subsequently take out a substrate from load lock 20 without having to move to or from the load lock empty-handed, which may be the case if both the coming and going substrate took up the same position.

As an alternative, cover plate 28 may be omitted. In this case only support table 24 provides temperature stabilization. However, use of a cover plate 28 may make the arrangement more effective because heat conduction through, for example, a semi-conductor substrate from the side of the support table 24 may be small.

FIG. 2d shows an embodiment in which support pins 26 have been omitted. In this embodiment substrate W is placed directly on support table 24. To allow for a gripper that reaches under substrate W, in this embodiment the width of support table 24 on at least part of the periphery of support table 24 is less than the width of substrate W, so that substrate W when over support table 24 horizontally extends beyond the periphery of support table 24 on, for example, two mutually opposite sides. In an embodiment, the extension is not significantly more than needed for a gripper, so that for example less than 80 percent of the area of substrate W extends beyond the periphery of support table 24. Thus good heat conduction may still be provided. As in the embodiments of FIGS. 2a-c, support table 24 may be raised towards cover plate 28 after placement of substrate W in load lock 20. Alternatively or additionally, cover plate 28 may be lowered.

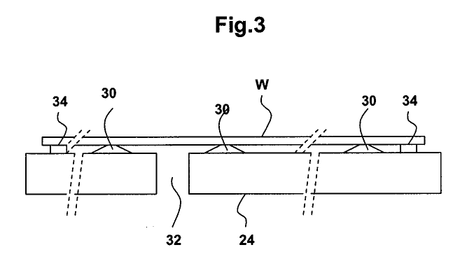

FIG. 3 shows a detail of a substrate W and support table 24 according to an embodiment of the present invention. In the embodiment shown, an array of bumps 30 is provided on support table 24. Optionally a ring 34 extending from support table 24 around the collection of bumps may be provided, peripherally enclosing an area that has a width that is smaller than the width of substrate W. All bumps 30 have substantially equal height, so that a virtual surface with plane segments extending between the tips of bumps 20 is substantially parallel to the surface of support table 24 outside the bumps (which may be a flat plane) and substrate W may rest on bumps 30. Bumps 30 of 10 microns high may be used for example (the bumps are shown with exaggerated height). A considerable number of bumps 30 may be provided, for example at mutual distances selected between approximately 1-10 mm. When substrate W rests on bumps 30, the distance between substrate W and support table 24 is made small. Bumps 30 leave a space between support table 24 and substrate W wherein gas is present, the gas significantly improving heat transport from support table 24 to substrate W. Heat transport is efficient because the space between substrate W and support table 24 is kept very small. In an embodiment holes 32 (one shown by way of example) may be provided in support table 24 to allow supply of gas into the space between support table 24 and substrate W. The height of bumps 30 is selected as a compromise: small height has an advantage of improving thermal transport through the gas but small height also has a disadvantage of making the distribution of gas more difficult. This problem may be reduced by using a large number of holes 32, for example 10-50 holes underneath the substrate, to allow supply of gas. Optional ring 34 may reduce lateral gas flow from the space between substrate W and support table 24 into load lock 20. In an embodiment, the height of this ring is slightly less than that of bumps 30, for example between approximately 0.2 and 5 micrometers less high, to avoid contact with substrate W.

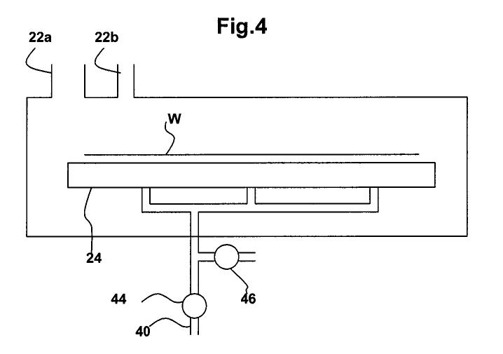

FIG. 4 shows an embodiment wherein a separate pump connection 40 is provided to partly remove gas from the space between support table 24 and substrate W. Holes are provided in support table 24 to remove the gas. In an embodiment, there are separate holes 32 to allow supply of and removal gas. In another embodiment, the same holes may be used, alternately coupled to a gas supply and separate pump connection 40. Valves 44, 46 are provided to switch the connection to the holes for removing gas, between pump connection 40 and the space in load lock 20. The holes for removing gas are connected to valves 44, 46, for example via a cavity in support table 24, or via gas conduits. Separate pumps may be connected to separate pump connection 40 and the main pump connection 22a of the load lock. Alternatively the same pump may be connected to both connections, but more directly to separate pump connection 40 than to the main pump connection 22a, so that initially a lower pressure is realized via separate pump connection 40.

In operation, separate pump connection 40 is used to reduce the pressure of gas between support table 24 and substrate W to a predetermined non-zero pressure level, for example to a pressure in the range of approximately 0.5-0.8 bar or lower, initially when substrate W has been placed in load lock 20 and support table 24 has been raised. This pressure is reduced more quickly than the pressure above substrate W. Thus, substrate W is initially clamped to support table 24 on bumps 30 by the effect of the pressure difference. This straightens substrate W, reducing the distance to support table 24 and thereby increasing thermal conduction between substrate W and support table 24. The predetermined non-zero pressure is maintained to promote heat transport. This predetermined non-zero pressure is maintained until the pressure above substrate W approaches the predetermined non-zero pressure. Then the holes for removing gas are coupled to load lock pressure, for example by switching valves 44, 46. Thus the pressure between support table 24 and substrate W is subsequently lowered together with pressure above substrate W, or in advance of the lowering pressure above substrate W. This prevents substrate W from being blown off support table 24. Of course this has an effect that the thermal conductivity between substrate W and support table 24 also reduces, because substrate W is no longer clamped and because pressure drops, but the main heat transport due to adiabatic expansion occurs at highest pressures in load lock 20, i.e. when substrate W is still clamped. Only a small effect occurs once the pressure has been sufficiently reduced.

Alternatively, or in addition, electrostatic clamping may be used to keep substrate W on support table 24. This may be achieved for example by placing different electric voltages on different parts of support table 24 that face substrate W. Electrostatic clamping serves to keep substrate on support table 24 even when gas is present between support table 24 and substrate W at a higher pressure than above substrate W. In this case holes 32 may be omitted or connected so that the pressure between support table 24 and substrate W is maintained, or at least reduced slower than the pressure in load lock 20 as a whole. This improves heat transport between support table 24 and substrate W.

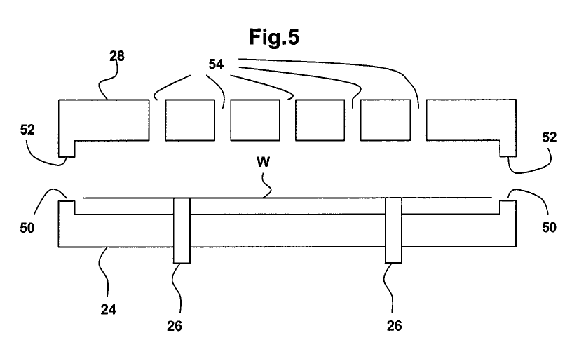

FIG. 5 shows an embodiment wherein ridges 50, 52 are provided near the edges of support table 24 and cover plate 28. Substrate W fits between ridges 50, 52 on diametrically opposite sides of support table 24 and cover plate 28. As used herein, “fitting” means that there is sufficient room for substrate W when the ridge runs around substrate W, or substantially around it in the sense that the substrate cannot be moved out laterally. No exact fit is needed.

Holes 54 are provided in cover plate 28. Holes 54 serve to allow removal of gas from above substrate W. Ridges 50, 52 serve to reduce gas flow from or to the periphery of substrate W. Instead of ridges 50, 52 on both support table 24 and cover plate 28, one or more ridges 50 on only support table 24 or one or more ridges 52 on only cover plate 28 may be used to obstruct gas flow. Holes 54 may each have a width of approximately 1-10 mm, and between for example 5-50 holes 54 may be used. In an embodiment, 1 to 50 percent of the surface of cover plate 24 may be open in holes 54.

Holes 54 have the effect that gas flows upwards from substrate W when load lock is depressurized. Thus, lateral gas flow across the entire surface of substrate W is reduced. This reduces temperature inhomogeneity and cooling of substrate W. It may be noted that holes need not extend vertically to have this effect; it suffices that the initial gas flow at the hole at the lower surface has a vertical component.

Ridges 50, 52 are optional. Ridges 50, 52 reduce gas lateral flow over the edges of substrate W towards and from load lock 20. This may further reduce temperature inhomogeneity and cooling of substrate W. As will be understood, this effect may be achieved with ridges 50, 52 on both support table 24 and cover plate 28, or with one or more ridges 50, 52 on only one of them. Use of ridge(s) 52 on cover plate 28 has an advantage that there is no obstruction to placement of the substrate W on support table 24. In an embodiment, the ridge or ridges 50, 52 extends along the entire periphery. Alternatively, small interruptions may be present in the ridges. As long as these interruptions do not extend over a considerable distance, such as a distance that would allow substrate W to be moved in and out laterally, an improvement of temperature homogeneity and stability may be realized. As noted, ridges 50, 52 are optional. Even without the reduction by ridges 50, 52 the use of holes 54 may improve temperature stability. Ridges 50, 52 further improve temperature stability.

In an embodiment, cover plate 28 may be temperature stabilized like support table 24. However, even without stabilization of cover plate 28 an improved effect may be realized, as heat transport from cover plate 28 to substrate W is small due to the relatively large distance between the two. The heat transport may be improved by decreasing the distance between cover plate 28 and support table 24 so that the distance between cover plate 28 and substrate W is reduced from, for example, 10 mm to 3 mm. Ridges 50, 52 may touch each other at this reduced distance.

Although an embodiment is shown wherein holes 54 connect the region over substrate W to a remainder of load lock 20, it should be appreciated that holes 54 may as well connect to any other space that is at the same pressure as load lock 20. In an embodiment cover plate 24 is part of the ceiling of load lock 20. If holes 54 connect to another space, the pressure in that space is, in one embodiment, the same as in load lock 20 to avoid causing gas flow across the periphery. However, if the periphery is sealed off, cover plate 28 and support table 24 effectively form another load lock. In this case the pressure in the other space may be higher or lower than the pressure in the remainder of the main load lock 20.

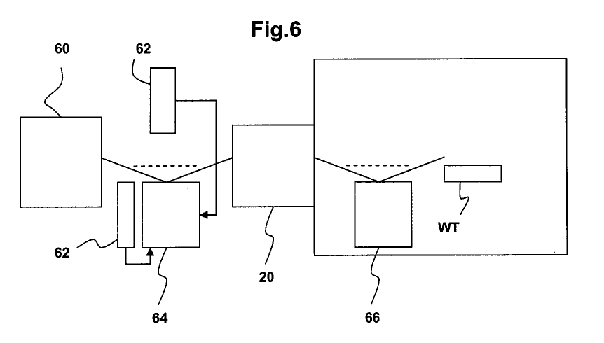

FIG. 6 shows a lithographic processing system including a photoresist coating applicator 60, an inspection device 62, a load lock 20 and a substrate table WT in a vacuum space, with robots 64, 66 to move substrates W in and out of load lock 20 between load lock 20 and coating applicator 60 and substrate table WT respectively. Inspection device 62 is located between load lock 20 and coating applicator 60, or in coating applicator 60. In an embodiment, inspection device 62 is configured to inspect selected parts of substrate W that will not be illuminated with patterned beam PB, but come into contact with handling and support devices, such as the back side of substrate W (i.e. the side opposite the side covered with photoresist), an edge of substrate W and/or an edge region at the front side of substrate W adjoining an edge of the substrate W. In an embodiment, inspection device 62 is also configured to inspect parts of substrate W that will be illuminated with patterned radiation. Inspection device 62 may be an optical inspection device configured to detect traces of photoresist material. As shown, inspection device 62 may have several parts, for inspecting the front side and the back side of substrate W respectively. When inspection device 62 detects no trace of photoresist material on the selected parts of substrate W, it sends a signal to robot 64 to allow substrate W to be moved into load lock 20. A move of substrate W into load lock 20 is prevented in response to an indication that at least a trace of photoresist material has been detected on at least one of the selected parts. In this way contamination of load lock 20, which could lead to long down times, is reduced. Robot 64 is programmed to move substrate W to a reject receptacle (not shown) when the signal indicates that a trace of photoresist material has been detected on at least one of the selected parts.

In an embodiment, the inspection is performed outside load lock, that is, before evacuating the atmosphere about substrate W. This simplifies inspection and reduces the risk that contamination will get loose due to evacuation. In an embodiment, the substrate is held or supported by a temperature stabilized structure (not shown) during the inspection and optionally in a temperature stabilized atmosphere. The structure may be temperature stabilized by means of one or more conduits that pass fluid that is used to stabilize the temperature of support table 24. The atmosphere may be stabilized by passing this fluid through a wall adjacent the location of inspection. By applying temperature conditioning during inspection the time needed for inspection can be used to prepare the substrate temperature. This may reduce the demand on temperature stabilization by load lock 20.

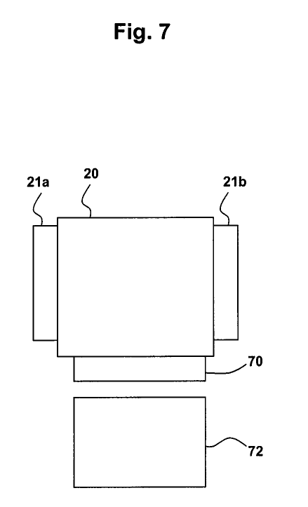

FIG. 7 shows a top view of a load lock 20, including first and second doors 21a,b plus an additional door 70. First door 21a couples load lock 20 to photoresist coating applicator 60. Additional door 70 allows one or more substrates to be entered from an auxiliary module 72. In operation, additional door 70 is used to enter substrates for special operations, such as cleaning and/or calibration, without passing through photoresist coating applicator 60. This makes it possible to perform such special operations without using an additional load lock and without decoupling photoresist coating applicator 60. In particular, the special operations may be performed when photoresist coating applicator 60 is temporarily out of use, for example for maintenance. In an example of a special cleaning operation, a pre-cleaned substrate is entered through additional door 70 and placed on one or more positions where substrates are normally in contact with the lithographic apparatus during processing, to pick up contamination from such positions. This may include positions in load lock 20 and/or in the main vacuum space. Thus cleaning can be performed. In another application, a substrate with calibration structures may be entered through additional door 70 to perform calibration measurements in the lithographic apparatus. The substrate used in such operations may subsequently be removed again through additional door 70. A standard substrate handler (carrier), such as a known FOUP handler may be used, where additional door 70 has a size and shape configured to enable coupling to such a handler. In each case, first door 21a for photoresist coating applicator 60 is not needed to supply and/or remove a substrate for such special operations. Typically, no devices are manufactured from the substrate for special operations, but such manufacture is not prevented.

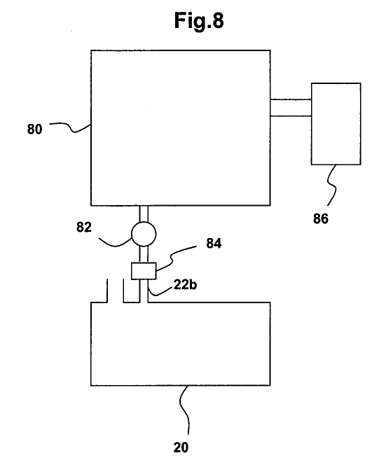

FIG. 8 shows an embodiment of the apparatus including load lock 20, a buffer vessel 80, a valve 82, a diffuser 84 and a pressure regulator 86. Buffer vessel 80 is connected to venting connection 22b of load lock 20 successively via valve 82 and diffuser 84. Pressure regulator 86 is coupled to buffer vessel 80. A control circuit, such as a programmed computer, controls operation of valve 82 and pressure regulator 86. In operation, the control circuit closes valve 82 until load lock 20 is vented. While valve 82 is closed pressure regulator 86 is activated. When active, pressure regulator 86 regulates gas pressure in buffer vessel 80 to a certain pressure, for example by adding or removing gas from buffer vessel 80. When a substrate W is transferred from the vacuum space of the lithographic apparatus to the outside of the lithographic apparatus, substrate W is inserted in load lock 20. When doors 21a,b of load lock 20 are closed, pressure regulator 86 is deactivated and valve 82 is opened, allowing gas to flow from buffer vessel 80 through diffuser 84 to load lock 20. Thus the pressure in load lock 20 and buffer vessel 80 are equalized. In an embodiment, the regulated pressure in buffer vessel 80 is selected so that after pressure equalization the pressure in load lock 20 equals or slightly exceeds the outside pressure. In an embodiment, the volume of buffer vessel 80 is as large as the volume of load lock 20. This prevents strong gas flow. Alternatively, a smaller vessel at a higher pressure may be used, in combination with a gas flow resistance and/or particle filter coupled between buffer vessel 80 and load lock 20. This may be used to increase venting speed. Pressure regulation in buffer vessel 80 may take place slowly, during almost the entire time interval when valve 82 is closed, and pressure equalization with gas from a buffer vessel that does not have very high pressure also avoids strong flow. Diffuser 84 further reduces flow speed.

Although one load lock for transporting substrates to a substrate table WT in a vacuum space has been shown in the Figures, it should be appreciated that the lithographic apparatus may have a plurality of similar load locks in parallel. Thus, cycle time can be gained by entering a substrate in one load lock while the other load lock or load locks are being evacuated or vented. In an embodiment, once a substrate has been taken out of a load lock another substrate is inserted while the relevant door remains open. Thus one evacuation-venting cycle can be used for a plurality of substrates.

Although embodiments have been shown where the same load lock is used both to transport substrates to the vacuum space and to transport substrates from the vacuum space, it should be appreciated that as an alternative specialized load locks for one way transport may be used. In that case, components such as support table 24 and cover plate 28 may be provided in the load lock for transport towards the vacuum space. They need not necessarily be used in the load lock for transport from the vacuum space. The same goes for the use of the inspection device. Use of a load lock for transport in two directions has an advantage that fewer load locks are needed. This results in little loss of processing cycle time since most of the cycle time is used to evacuate and vent a load lock, which has to be performed for all load locks.

Although a configuration has been shown wherein the load lock opens directly into the vacuum chamber, it should be realized that one or more intermediate chambers may be present between the load lock and the main vacuum chamber. Also a plurality of robots may be used to perform successive transport steps.

Although a configuration has been shown wherein substrate W rests horizontally in load lock 20, it should be appreciated that, when clamping is used, any other orientation may be used. In this respect, terms like “upper” and “lower” which correspond to vertically upper and lower when the substrate is oriented horizontally, are used according to a generalized sense of upper-lower direction, wherein the surface of substrate that is to be patterned is in the upper direction relative to the opposite surface of the substrate, which is in the lower direction.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g. having a wavelength of or about 365, 355, 248, 193, 157 or 126 nm) and extreme ultra-violet (EUV) radiation (e.g. having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

While specific embodiments of the invention have been described above, it will be appreciated that the invention may be practiced otherwise than as described. For example, the invention may take the form of a computer program containing one or more sequences of machine-readable instructions describing a method as disclosed above, or a data storage medium (e.g. semiconductor memory, magnetic or optical disk) having such a computer program stored therein.

The descriptions above are intended to be illustrative, not limiting. Thus, it will be apparent to one skilled in the art that modifications may be made to the invention as described without departing from the scope of the claims set out below.

### CONCLUSION

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

Embodiments of the present invention have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

1.-30. (canceled)

31. A substrate processing apparatus with a processing chamber, the apparatus comprising:
a load lock for gas removal, with a first door to allow entry of a substrate and a second door to allow exit of the substrate directly or indirectly to the processing chamber;
a support table, in the load lock, having an upper surface to support the substrate; and
a cover plate in the load lock, the cover plate having a lower surface facing the upper surface of the support table, wherein openings are provided in the lower surface of the cover plate to allow removal of gas from above the substrate in a direction substantially normal to the lower surface.

32. A substrate processing apparatus according to claim 31, wherein the openings allow removal of gas to a remainder of the load lock or a space having a same gas pressure as the remainder of the load lock.

33. A substrate processing apparatus according to claim 31, wherein the cover plate has a width that is larger than a width of the substrate and wherein a ridge is provided along an edge of at least one of the support table and the cover plate, extending from at least one of the upper surface of the support table and the lower surface of the cover plate, the substrate fitting within the ridge.

34. A substrate processing apparatus according to claim 31, comprising a driving mechanism configured to move at least one of the upper surface of the support table and the lower surface of the cover plate relative to each other in a direction substantially normal to these surfaces.

35. A substrate processing apparatus according to claim 31, wherein the cover plate is temperature stabilized.

36. A substrate processing apparatus according to claim 31, wherein the support table is temperature stabilized.

37. A substrate processing apparatus according to claim 31, further comprising:
a plurality of bumps of approximately equal height, on an upper surface of the support table, to support the substrate;
a gas removing arrangement comprising an opening in the upper surface of the support table, the gas removing arrangement being configured to reduce a gas pressure between the upper surface of the support table and the substrate initially through the opening in the upper surface of the support table to a certain pressure below a concurrent load lock pressure in a remainder of the load lock, and to reduce the gas pressure between the upper surface of the support table and the substrate together with the load lock pressure in the remainder of the load lock when the load lock pressure in the remainder of the load lock has dropped below the certain pressure.

38. A substrate processing apparatus according to claim 37, comprising support pins extending through holes in the support table and a driving mechanism configured to move the support table relative to the support pins at least between a first position wherein the support pins extend upward from the support table and a second position where an upper surface of the support table is raised level with or above tops of the support pins.

39. A substrate processing apparatus according to claim 31, which substrate processing apparatus is a lithographic apparatus, the substrate processing apparatus further comprising:
a support constructed to support a patterning device, the patterning device being capable of imparting a radiation beam with a pattern in its cross-section to form a patterned radiation beam;
a substrate table constructed to hold a substrate in the processing chamber; and
a projection system configured to project the patterned radiation beam onto a target portion of the substrate in the processing chamber.

40. A substrate processing apparatus with a processing chamber, the apparatus comprising:
a load lock for gas removal, with a first door to allow entry of a substrate and a second door to allow exit of the substrate directly or indirectly to the processing chamber;
a temperature stabilized support table in the load lock to support the substrate, the support table comprising a plurality of bumps of approximately equal height on an upper surface of the support table; and
a gas removing arrangement comprising an opening in the upper surface of the support table, the gas removing arrangement being configured to reduce a gas pressure between the upper surface of the support table and the substrate initially through the opening to a certain pressure below a concurrent load lock pressure in a remainder of the load lock, and to reduce the gas pressure between the upper surface of the support table and the substrate together with the load lock pressure in the remainder of the load lock when the load lock pressure in the remainder of the load lock has dropped below the certain pressure.

41. A substrate processing apparatus according to claim 40, comprising support pins extending through holes in the support table and a driving mechanism configured to move the support table relative to the support pins at least between a first position wherein the support pins extend upward from the support table and a second position where an upper surface of the support table is raised level with or above tops of the support pins.

42. A substrate processing apparatus according to claim 40, wherein the support table has a width that is larger than a width of the substrate.

43. A substrate processing apparatus according to claim 40, which substrate processing apparatus is a lithographic apparatus, the substrate processing apparatus further comprising:
a support constructed to support a patterning device, the patterning device being capable of imparting a radiation beam with a pattern in its cross-section to form a patterned radiation beam;
a substrate table constructed to hold a substrate in the processing chamber; and
a projection system configured to project the patterned radiation beam onto a target portion of the substrate in the processing chamber.

44-50. (canceled)

51. A device manufacturing method, comprising:
inserting a substrate into a load lock over a temperature stabilized support table, the support table comprising a plurality of approximately equal height bumps on an upper surface of the support table supporting the substrate, an opening being present in the upper surface of the support table;
reducing a gas pressure between the upper surface of the support table and the substrate initially to a certain pressure below a concurrent load lock pressure in a remainder of the load lock by removing gas through the opening from a space between the upper surface of the support table and the substrate, when the substrate rests on the bumps;
reducing the gas pressure between the upper surface of the support table and the substrate together with the load lock pressure in the remainder of the load lock when the load lock pressure in the remainder of the load lock has dropped below the certain pressure;
passing the substrate to a processing chamber through the load lock; and
processing the substrate in the processing chamber.

52. A device manufacturing method according to claim 51, further comprising providing a cover plate located in the load lock with the cover plate having a lower surface facing an upper surface of the substrate.

53. A device manufacturing method according to claim 52, further comprising moving at least one of the upper surface of the support table and the lower surface of the cover plate towards each other after the substrate has been placed over the upper surface of the support table.

54. A device manufacturing method according to claim 52, further comprising removing gas from a space above the substrate through openings in the lower surface of the cover plate.

55. A device manufacturing method according to claim 54, further comprising obstructing gas flow from a periphery of the substrate towards its center.

56. A device manufacturing method according to claim 51, further comprising projecting a patterned beam onto the substrate in the processing chamber.

57-60. (canceled)
